(19) United States
(12) Patent Application Publication
(10) Pub. No.: US 2004/0155293 A1
(43) Pub. Date: Aug. 12, 2004

(54) Semiconductor device with ESD protection

(76) Inventors: Kei-Kang Hung, Changhua County (TW); Yi-Hwa Chang, Hsinchu County (TW)

Correspondence Address: MARTINE & PENILLA, LLP, 710 LAKEWAY DRIVE, SUITE 170, SUNNYVALE, CA, 94085, US

(21) Appl. No.: 10/749,982

(22) Filed: Dec. 30, 2003

Related U.S. Application Data
(62) Division of application No. 10/133,145, filed on Apr. 26, 2002.

(51) Int. Cl. H01L 23/62

(52) U.S. Cl. 257/355

(57) ABSTRACT

The invention provides a semiconductor device with ESD protection including a guard ring and a MOS transistor array formed in a region surrounded by the guard ring. In the invention, the MOS transistor array includes a first MOS transistor and a second MOS transistor. The first MOS transistor is closer to the guard ring than the second MOS transistor is. The channel length of the second MOS transistor is greater than that of the first MOS transistor.

### RELATED APPLICATIONS

This is a Divisional application claiming priority under 35 U.S.C. §120, of co-pending prior application Ser. No. 10/133,145 filed on Apr. 26, 2002, the disclosure of which is incorporated herein by reference.

### BACKGROUND OF THE INVENTION

1. Field of the Invention

The invention relates to a semiconductor device and, more particularly, to a semiconductor device with electrostatic discharge (ESD) protection.

2. Description of the Related Art

The electrostatic protection is one of the important fields of the integrated circuits. Since the electrostatic charge is accompanied with a relatively high voltage (may be thousand volts), those skilled in the art may utilize an electrostatic discharge (ESD) protection circuit to protect the semiconductor device, thereby preventing the semiconductor device from being damaged by the electrostatic charge.

FIG. 1A is a schematic illustration showing a circuit layout of a conventional semiconductor device 1 with ESD protection. Referring to FIG. 1A, the semiconductor device 1 includes a guard ring 11 and a MOS (Metal-Oxide-Semiconductor) transistor array 12. The MOS transistor array 12 has a plurality of MOS transistors, each of which is composed of a source 121, a drain 122 and a gate 123. Since the circuit layout of the gate 123 looks like a finger, the semiconductor device shown in FIG. 1A is of a finger-type. FIG. 1B is a schematic illustration showing a cross-sectional view of the semiconductor device taken along a line AA′ in FIG. 1A. As shown in FIG. 1B, a plurality of N⁺ diffusion areas and a plurality of P⁺ diffusion areas are formed on a substrate 20. The N⁺ diffusion areas 21 and 22 serve as the source 121 and the drain 122 shown in FIG. 1A, respectively The P⁺ diffusion area 23 serves as the guard ring 11 shown in FIG. 1A. The N⁺ diffusion areas 21 and 22 and the substrate 20 form a first parasitic bipolar junction transistor (parasitic BJT) 24. Thus, the electrostatic charge, such as of a human-body mode (HBM), can be discharged from the parasitic BJT 24 so that the MOS transistor array 12 can be protected.

According to the same principle, the N⁺ diffusion areas 22 and 25 and the substrate 20 also form a second parasitic BJT 26 (as shown in FIG. 1B). The electrostatic charge can also be discharged from the second parasitic BJT 26 so that the MOS transistor array 12 can be protected. In addition, the distance between the N⁺ diffusion areas 21 and 22 is a channel length L1, and the distance between the N⁺ diffusion areas 22 and 25 is a channel length L2. Basically, the channel length L1 is equal to the channel length L2. Theoretically, the more the parasitic BJTs are formed within the semiconductor device, the larger ESD robustness the semiconductor device has. In other words, in the finger-type semiconductor device with ESD protection, since the unit finger width is fixed (e.g., 30 μm), the ESD robustness of the semiconductor device rises with the increase in the number of fingers. However, since the distance D2 between the second parasitic BJT 26 and the P⁺ diffusion area 23 is greater than the distance D1 between the first parasitic BJT 24 and the P⁺ diffusion area 23 (as shown in FIG. 1B), the second substrate resistor R_{sub2} is larger than the first substrate resistor R_{sub1}. When the ESD event happens, a base hole current is generated at the P-N junction. At this time, the potential at the base of the second parasitic BJT 26 is greater than that of the first parasitic BJT 24. Thus, the second parasitic BJT 26 is turned on early, resulting in the snapback phenomenon, and the potential is clamped at the snapback voltage. Thereby, the snapback phenomenon becomes more difficult to happen in the parasitic BJTs of other fingers (this problem has been referred to as turn-on non-uniformity). That is, the central portion of the MOS transistor array 12 (as shown in FIG. 1A) reaches the second breakdown current earlier than other portions (as shown in FIG. 2). Also, the theoretical ESD robustness of the human-body mode equals to the product of the second breakdown current and the equivalent resistor of the human-body mode (1.5 kΩ). To sum up, the MOS transistor forming the second parasitic BJT 26 reaches the limit of the ESD robustness and is damaged early. In other words, since the turn-on speeds of the fingers are different from one another, the turn-on uniformity is not good. Thus, the ESD protection ability of the semiconductor device does not come up to expectation.

As stated above, in order to overcome the above-mentioned problem, those skilled in the art may improve the turn-on uniformity of each finger by various circuit tricks. For example, a substrate-triggered area (not shown) may be provided between the MOS transistor forming the first parasitic BJT 24 and the MOS transistor forming the second parasitic BJT 26. However, these circuit tricks may result in the increased area of the circuit layout, thereby increasing the costs.

To sum up, it is very important to improve the turn-on uniformity of each finger without greatly increasing the area of the circuit layout.

### SUMMARY OF THE INVENTION

In view of the above-mentioned problem, it is an important object of the invention to provide a semiconductor device with ESD protection capable of improving the turn-on uniformity of each finger without greatly increasing the area of the circuit layout.

To achieve the above-mentioned object, the semiconductor device with ESD protection in accordance with the invention includes a guard ring and a MOS transistor array. In one aspect of the invention, the MOS transistor array is formed in a region surrounded by the guard ring and comprises a first MOS transistor and a second MOS transistor. In this aspect, the first MOS transistor is closer to the guard ring than the second MOS transistor is, and the channel length of the second MOS transistor is greater than that of the first MOS transistor.

In addition, in another aspect of the invention, the semiconductor device with ESD protection according to the invention further includes a first resistor and a second resistor. A gate of the first MOS transistor is electrically connected to one end of the first resistor, and a gate of the second MOS transistor is electrically connected to one end of the second resistor. The other ends of the first resistor and the second resistor are grounded. The channel length of the second MOS transistor is equal to that of the first MOS transistor, and the resistance value of the first resistor is greater than that of the second resistor.

In still another aspect of the invention, the MOS transistor array includes a plurality of NMOS transistors with the same channel length. Parts of the gates of the MOS transistors are electrically connected and constitute a first finger, while parts of the gates of the MOS transistors are electrically connected and constitute a second finger. The first finger is closer to the guard ring than the second finger is, and the second finger width is greater than the first finger width.

In addition, a semiconductor device with an ESD protective combination according to the invention includes a first guard ring, a second guard ring, a first MOS transistor array formed in a region surrounded by the first guard ring, and a second MOS transistor array formed in a region surrounded by the second guard ring. In this aspect, the first MOS transistor array has a plurality of MOS transistors while the second MOS transistor array has a plurality of MOS transistors. The channel length of each of the MOS transistors in the second MOS transistor array is greater than that of each of the MOS transistors in the first MOS transistor array.

As stated above, the semiconductor device with ESD protection in accordance with the invention provides MOS transistors having different channel lengths, MOS transistors connecting to different resistors, fingers with different widths, or MOS transistors having different channel lengths surrounded by different guard rings according to the distances between the MOS transistors and the guard rings. In other words, only a slight size modification of the circuit layout needs to be made in this invention. Therefore, it is possible to improve the turn-on uniformity of each finger without greatly increasing the area of the circuit layout.

### BRIEF DESCRIPTION OF THE DRAWINGS

FIG. 1A is a schematic illustration showing a circuit layout of a conventional semiconductor device with ESD protection, wherein the channel lengths of the MOS transistors are equivalent.

FIG. 1B is a schematic illustration showing a cross-sectional view of the semiconductor device taken along a line AA′ in FIG. 1A.

FIG. 2 is a schematic illustration showing the non-uniformity as the MOS transistor array is turned on when the semiconductor device shown in FIG. 1A discharges electrostatic charge.

FIG. 3A is a schematic illustration showing a circuit layout of a semiconductor device with ESD protection in accordance with a preferred embodiment of the invention.

FIG. 3B is a schematic illustration showing a cross-sectional view of the semiconductor device taken along a line BB′ in FIG. 3A.

FIG. 4 is a schematic illustration showing a circuit layout of a semiconductor device with ESD protection in accordance with another preferred embodiment of the invention.

FIG. 5 is a schematic illustration showing a circuit layout of a semiconductor device with ESD protection in accordance with still another preferred embodiment of the invention.

FIG. 6 is a schematic illustration showing the circuit layout of a semiconductor device with an ESD protective combination in accordance with a preferred embodiment of the invention.

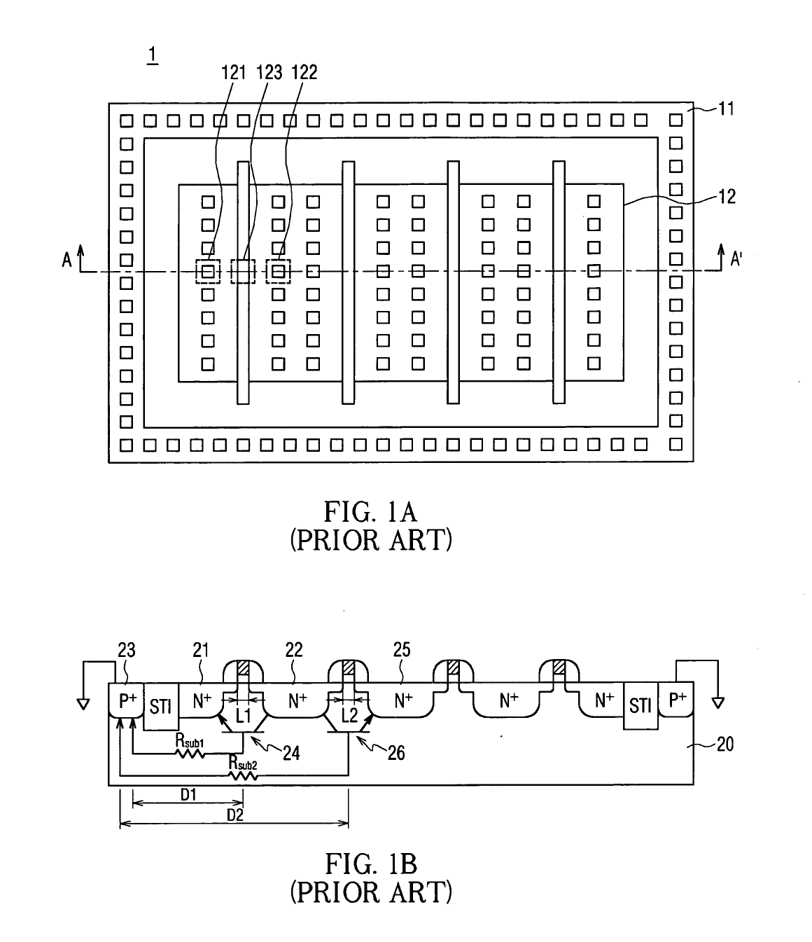

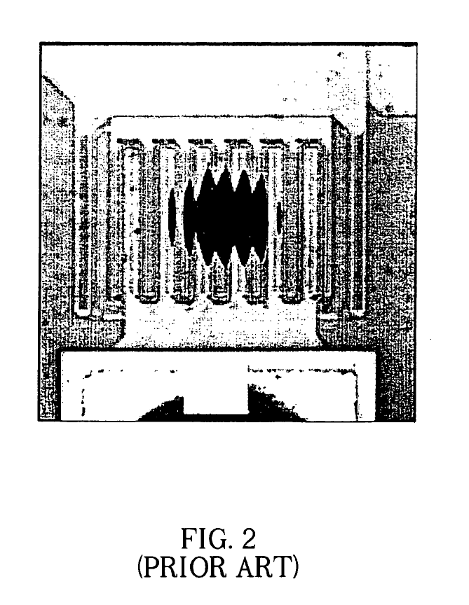

### DETAILED DESCRIPTION OF THE PREFERRED EMBODIMENTS

The semiconductor device with ESD protection in accordance with preferred embodiments of the invention will be described with reference to the accompanying drawings, wherein the same reference numbers denote the same elements.

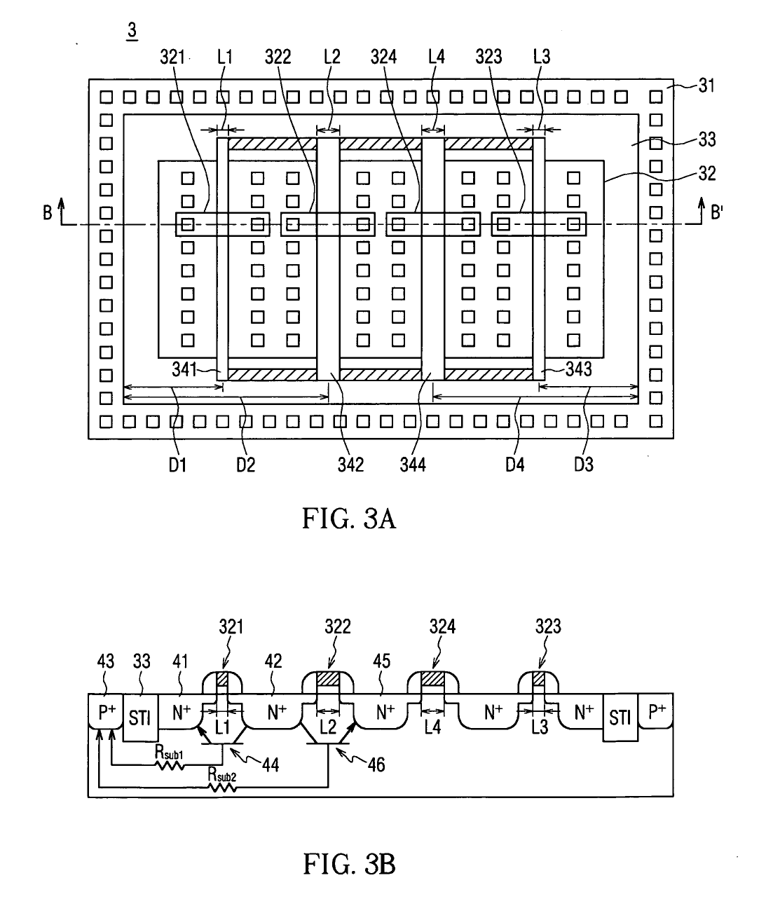

Referring to FIG. 3A, a semiconductor device 3 with electrostatic discharge protection in accordance with a preferred embodiment of the invention includes a guard ring 31 and a MOS transistor array 32 formed in a region surrounded by the guard ring 31. The MOS transistor array 32 includes a first MOS transistor 321, a second MOS transistor 322, a third MOS transistor 323 and a fourth MOS transistor 324. The first MOS transistor 321 is closer to the guard ring 31 than the second MOS transistor 322 is. The third MOS transistor 323 is closer to the guard ring 31 than the fourth MOS transistor 324 is. The channel length L2 of the second MOS transistor 322 is greater than the channel length L1 of the first MOS transistor 321. The channel length L4 of the fourth MOS transistor 324 is greater than the channel length L3 of the third MOS transistor 323. As shown in this drawing, the channel lengths L1, L2, L3 and L4 are the lengths of a first finger 341, a second finger 342, a third finger 343 and a fourth finger 344, respectively. The distance D1 between the first MOS transistor 321 and the guard ring 31 is equal to the distance D3 between the third MOS transistor 323 and the guard ring 31. Correspondingly, the channel length L1 is equal to the channel length L3. The distance D2 between the second MOS transistor 322 and the guard ring 31 is equal to the distance D4 between the fourth MOS transistor 324 and the guard ring 31. Correspondingly, the channel length L2 is equal to the channel length L4. In this embodiment, the above-mentioned MOS transistors are NMOS transistors, and the gates of the MOS transistors are electrically connected together. That is, the fingers are electrically connected together. In addition, the gates (or fingers) of the MOS transistors are grounded. Such a design is of a gate-grounded type.

In addition, in the semiconductor device 3 with ESD protection in accordance with the preferred embodiment of the invention, an isolation portion 33 such as a shallow trench isolation (STI) portion is formed between the guard ring 31 and the MOS transistor array 32.

Next, how the semiconductor device 3 with ESD protection in accordance with the preferred embodiment of the invention discharges the electrostatic charge will be described with reference to FIG. 3B. FIG. 3B is a schematic illustration showing the cross-sectional view of the semiconductor device taken along a line BB′ in FIG. 3A. Taking the first MOS transistor 321 and the second MOS transistor 322 as examples, a first parasitic BJT 44 and a second parasitic BJT 46 can serve as ESD protection devices. In this embodiment, the channel length L1 (the distance between an N⁺ diffusion area 41 and an N⁺ diffusion area 42) is smaller than the channel length L2 (the distance between the N⁺ diffusion area 42 and an N⁺ diffusion area 45). As a result, the potential enabling the second parasitic BJT 46 to reach the first breakdown and enter the snapback breakdown region is greater than that enabling the first parasitic BJT 44 to reach the first breakdown. In other words, when the electrostatic charge flows into the semiconductor device 3, the first parasitic BJT 44 is turned on earlier than the second parasitic BJT 46 to discharge the electrostatic charge. In addition, as stated above, since the distance D2 between the second parasitic BJT 46 and a P⁺ diffusion area 43 is greater than the distance D1 between the first parasitic BJT 44 and the P⁺ diffusion area 43, the second substrate resistor R_{sub2} is larger than the first substrate resistor R_{sub1}. Therefore, the potential at the base of the second parasitic BJT 46 is greater than that at the base of the first parasitic BJT 44. That is, when the electrostatic charge flows into the semiconductor device 3, the second parasitic BJT 46 is turned on earlier than the first parasitic BJT 44 to discharge the electrostatic charge. To sum up, in the semiconductor device 3 with ESD protection in accordance with the preferred embodiment of the invention, the effects of each channel length and each substrate resistor on the turn-on of each parasitic BJT are simultaneously used. This enables the second parasitic BJT 46 and the first parasitic BJT 44 to be turned on simultaneously to discharge the electrostatic charge. That is, the electrostatic charge is discharged by improving the turn-on uniformity of each MOS transistor.

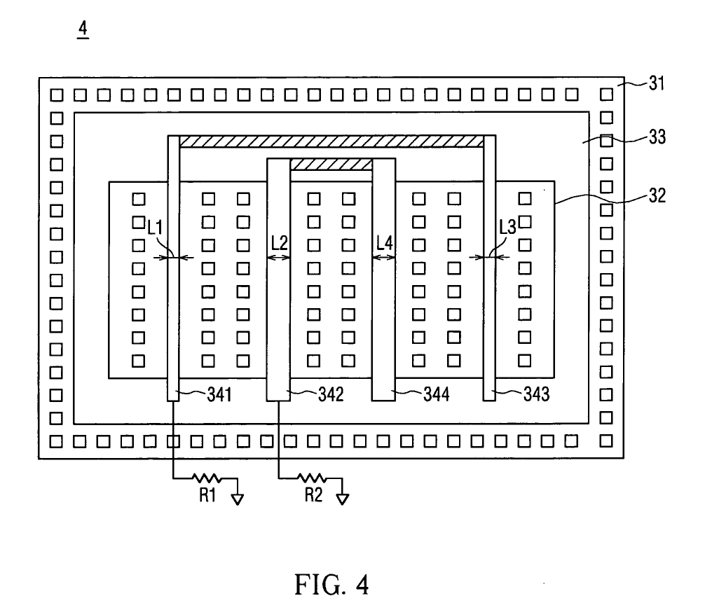

FIG. 4 is a schematic illustration showing a circuit layout of a semiconductor device 4 with ESD protection in accordance with another preferred embodiment of the invention. In this embodiment, one end of the first finger 341 is electrically connected to one end of the third finger 343, while the other end of the first finger 341 is electrically connected to a first resistor R1. On the other hand, one end of the second finger 342 is electrically connected to one end of the fourth finger 344, while the other end of the second finger 342 is electrically connected to a second resistor R2. In this embodiment, it should be noted that the resistance value of the first resistor R1 could be equal to that of the second resistor R2. Alternatively, the resistance value of the first resistor R1 can be greater than that of the second resistor R2. The function of the first resistor R1 and the second resistor R2 is to eliminate the effects of the first substrate resistor R_{sub1}, and the second substrate resistor R_{sub2} on the bases of the first parasitic BJT 44 and the second parasitic BJT 46 (as shown in FIG. 3B). It can be clearly understood to those skilled in the art that each finger and its corresponding base of the MOS transistor have the same semiconductor structure, and the length of each finger is the same as the corresponding channel length.

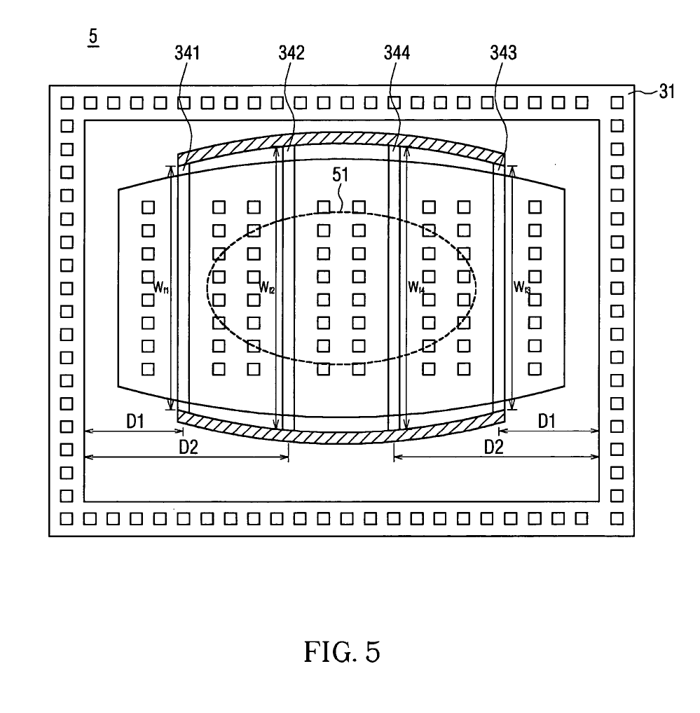

FIG. 5 is a schematic illustration showing a circuit layout of a semiconductor device 5 with ESD protection in accordance with still another preferred embodiment of the invention. As shown in FIG. 5, in this embodiment, the lengths of the fingers are all the same. That is, the channel lengths are all the same. On the other hand, based on differences of the distances between the fingers and the guard ring 31, the finger widths are formed different. Specifically, since the distance D2 between the second finger 342 and the guard ring 31 is greater than the distance D1 between the first finger 341 and the guard ring 31, the width W_{f2} of the second finger 342 is greater than the width W_{f1} of the first finger 341. Similarly, since the distance D4 between the fourth finger 344 and the guard ring 31 is greater than the distance D3 between the third finger 343 and the guard ring 31, the width W_{f4} of the fourth finger 344 is greater than the width W_{f3} of the third finger 343. As stated above, in the semiconductor device 5, a longer finger width is provided for the MOS transistor region 51 that can sustain a higher ESD level and then can survive long time enough to allow other parasitic BJTs which are closer to the guard ring 31, such as the second MOS transistor 322 and the fourth MOS transistor 324, to be turned on. This will improve the turn-on uniformity of each finger.

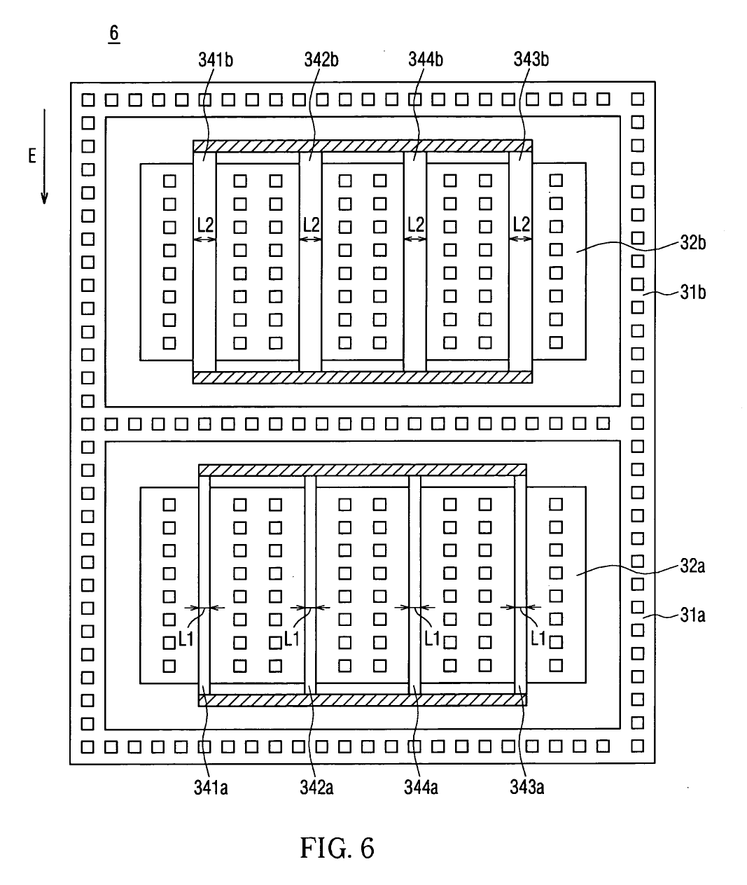

FIG. 6 is a schematic illustration showing a circuit layout of a semiconductor device with an ESD protective combination in accordance with a preferred embodiment of the invention. Referring to FIG. 6, the semiconductor device 6 of this embodiment includes a first guard ring 31a, a first MOS transistor array 32a formed in a region surrounded by the first guard ring 31a, a second guard ring 31b, and a second MOS transistor array 32b formed in a region surrounded by the second guard ring 31b. The first guard ring 31a is adjacent to the second guard ring 31b. The first MOS transistor array 32a has a plurality of MOS transistors and, also, the second MOS transistor array 32b has a plurality of MOS transistors. The channel length L2 of each of the MOS transistors (i.e., the length of each of fingers 341b to 344b) in the second MOS transistor array 32b is greater than the channel length L1 of each of the MOS transistors (i.e., the length of each of fingers 341a to 344a) in the first MOS transistor array 32a. Accordingly, when the direction of the electrostatic current is shown as an arrow E, the MOS transistors of the second MOS transistor array 32b and the first MOS transistor array 32a can be turned on simultaneously, thereby improving the turn-on uniformity of all MOS transistor arrays.

It should be understood to those skilled in the art that more (e.g., six or more than six) MOS transistors could be included in each MOS transistor array. Alternatively, each of the above-mentioned semiconductor devices can include more (e.g., six or more than six) fingers. In addition, the semiconductor device 6 also can include three or more than three guard rings and MOS transistor arrays.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A semiconductor device with an ESD protective combination, comprising:
a first guard ring;
a first MOS transistor array formed in a region surrounded by said first guard ring and having a plurality of MOS transistors;
a second guard ring adjacent to said first guard ring; and
a second MOS transistor array formed in a region surrounded by said second guard ring and having a plurality of MOS transistors, wherein a channel length of each of said MOS transistors in said second MOS transistor array is greater than that of each of said MOS transistors in said first MOS transistor array.

2. The semiconductor device according to claim 1, further comprising a first isolation portion formed between said first guard ring and said first MOS transistor array, and a second isolation portion formed between said second guard ring and said second MOS transistor array.

3. The semiconductor device according to claim 1, wherein gates of said MOS transistors in said first MOS transistor array are electrically connected to each other, and gates of said MOS transistors in said second MOS transistor array are electrically connected to each other.

4. The semiconductor device according to claim 1, wherein gates of said MOS transistors in said first MOS transistor array are grounded, and gates of said MOS transistors in said second MOS transistor array are grounded.
